(19) United States
(12) Patent Application Publication
(10) Pub. No.: US 2026/0068081 A1
(43) Pub. Date: Mar. 5, 2026

(54) ASYMETRIC FAN RAMP SPEED CONTROLLER

(71) Applicant: Dell Products L.P., Round Rock, TX (US)

(72) Inventors: ADOLFO SANDOR MONTERO, Pflugerville, TX (US); SURAJ M. VARMA, Portland, OR (US)

(21) Appl. No.: 18/820,585

(22) Filed: Aug. 30, 2024

(51) Int. Cl. H05K 7/20; F04D 27/00

(52) U.S. Cl. CPC H05K 7/20209; F04D 27/004

(57) ABSTRACT

Methods and systems for managing cooling and user experience of a data processing system are provided. In particular, one or more fans of the data processing system are controlled to realize an asymmetric fan ramp speed where the fans are controlled to ramp up at a first ramp speed slower than a second ramp speed at which the fan is controlled to ramp down. Controlling the fan to ramp up at the first ramp speed slower than the second ramp speed at which the fan is controlled to ramp down reduces an acoustic discomfort experienced by a user of the data processing system when the data processing system heats up.

### FIELD

Embodiments disclosed herein relate generally to managing data processing systems. More particularly, embodiments disclosed herein relate to systems and methods for managing cooling of data processing systems.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components and the components of other devices may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a block diagram illustrating a distributed system in accordance with one or more embodiments.

FIG. 2A shows a block diagram illustrating an example data processing system in accordance with one or more embodiments.

FIG. 2B shows a block diagram illustrating another example of a data processing system in accordance with an embodiment.

FIG. 3 shows a data flow diagram in accordance with one or more embodiments.

FIG. 4 shows a flowchart in accordance with one or more embodiments.

FIG. 5 shows a block diagram illustrating a data processing system in accordance with one or more embodiments.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for managing cooling and user experience of a data processing system. In particular, fans in computers (e.g., data processing systems) are generally controlled to ramp up and ramp down at the same ramp rate (i.e., to ramp up and ramp down in a symmetric manner).

Human nature is such that customers (i.e., users of the data processing systems) are more predisposed to notice when the fans start ramping up to keep the data processing systems cool as the internal component temperatures increase. Such ramping up of the fans generally create acoustic discomfort for the customers since the customers are aware that the louder fan speeds mean that their data processing systems are heating up.

However, under the same human nature, the same customers do not notice as readily the reduction in fan speed as the data processing systems cool back down even though such reduction is done at the same ramp rate as the increase in fan speed. As a result, such reduction when the fans are ramping down is not readily appreciated by these same customers who may derive satisfaction when knowing that their system is cooling down and is unable to be used to offset the acoustic discomfort experienced by these customers when system is heating up.

To overcome these limitations of such symmetrical ramp up and ramp down of the fans (e.g., such symmetric control of the fan ramp speed) and to better utilize the acoustics (e.g., fan ramp speed acoustics) generated during such ramp ups and ramp downs, embodiments disclosed herein provide an asymmetric fan ramp speed driver controller that controls the fans (or fan) to ramp up more slowly than when the fans are ramped down. Said another way, the ramp ups are slowed down to make the ramp ups less noticeable for a user of the data processing system, which in turn would make the ramp downs more noticeable for the user.

Such asymmetrical control of the fan ramp speeds capitalizes on the human nature discussed above to provide a mechanism within the data processing system that is advantageously able to improve user experience of the data processing system. Namely, by reducing the amount of acoustic discomfort experienced when the fans ramp up to better highlight when the fans ramp down, users are able to better appreciate when their data processing systems are cooling down without also having to be constantly reminded that their data processing systems are heating up.

As a result, an improvement in user experience technology is achieved through the asymmetric ramp speed control embodiments disclosed herein. Further, an improved data processing system that provides more comfort than discomfort (e.g., acoustically) to users is also obtained.

Additionally, there has always existed a long felt need for improving non-technical aspects (e.g., appearance, feel, sound, etc.) of data processing systems to better suit user preferences and needs and to provide better user satisfaction. More specifically, the looks, feeling and sounds of (e.g., associated with the user experience provided by) a data processing system are equally as important as the system’s technical offerings. The asymmetric ramp speed control of embodiments disclosed herein that reduces acoustic discomfort when a system heats up and increases user satisfaction when the system cools down advantageously solves such long felt need of data processing systems.

In an embodiment, a computer-implemented method for controlling a fan of a data processing system is provided. The method may include: controlling, using an asymmetric fan ramp speed driver controller of the data processing system, the fan to ramp fan speed asymmetrically based on a change in a system temperature of the data processing system.

Based on the change in the system temperature, the fan is controlled to ramp up at a first ramp speed slower than a second ramp speed at which the fan is controlled to ramp down.

The controlling may include: obtaining, by the asymmetric fan ramp speed controller, a first instance of the system temperature at a first point in time; using the first instance of the system temperature to determine a target fan speed, and an original fan ramp rate to get to the target fan speed from a current fan speed; and determining whether the first instance of the system temperature has increased since a last time, prior to the first point in time, the asymmetric fan ramp speed controller has obtained another instance of the system temperature.

The controlling further comprises in a first instance at the first point where the asymmetric fan driver has determined that the first instance of the system temperature has increased: making a first determination, based on determining that the first instance of the system temperature has increased, that the original fan ramp rate should be slowed down; and controlling, based on the first determination, the fan to reach the target fan speed at a slowed down rate of the original fan ramp rate.

The controlling further comprises in a second instance at the first point where the asymmetric fan driver has determined that the first instance of the system temperature has neither increased nor decreased: making a second determination, based on determining that the first instance of the system temperature has neither increased nor decreased, that the original fan ramp rate should remain the same; and controlling, based on the second determination, the fan to reach the target fan speed at the original fan ramp rate.

The controlling further comprises in a third instance at the first point where the asymmetric fan driver has determined that the first instance of the system temperature has decreased: making a third determination, based on determining that the first instance of the system temperature has decreased, that the original fan ramp rate should be sped-up; and controlling, based on the third determination, the fan to reach the target fan speed at a sped-up rate of the original fan ramp rate.

Controlling the fan to ramp up at the first ramp speed slower than the second ramp speed at which the fan is controlled to ramp down reduces an acoustic discomfort experienced by a user of the data processing system when the data processing system heats up.

A non-transitory media may include instructions that when executed by a processor cause the computer-implemented method to be performed.

The data processing system may include the non-transitory media and a processor, and may perform the computer-implemented method when the computer instructions are executed by the processor.

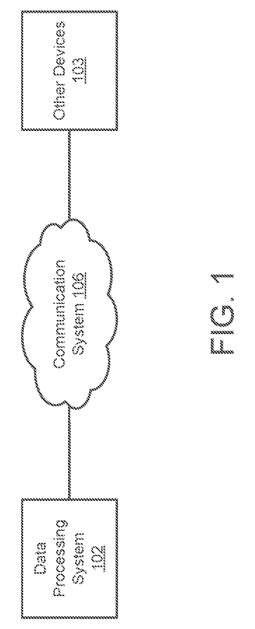

Turning to FIG. 1, a block diagram illustrating a distributed system in accordance with an embodiment is shown. The (distributed) system shown in FIG. 1 may provide computer-implemented services. The computer-implemented services may include any type and quantity of services including, for example data services (e.g., data storage, access and/or control services), communication services (e.g., instant messaging services, video-conferencing services), and/or any other type of service that may be implemented with a computing device.

The computer-implemented services may be provided by one or more components of the system of FIG. 1. For example, data processing system 102 may be implemented as any type of computing device (e.g., desktop computers, mobile phones, tablets, laptops, or the like) that may provide computer-implemented services. For example, the computer-implemented services may include data storage services, instant messaging services, database services, and/or any other type of service that may be implemented with a computing device.

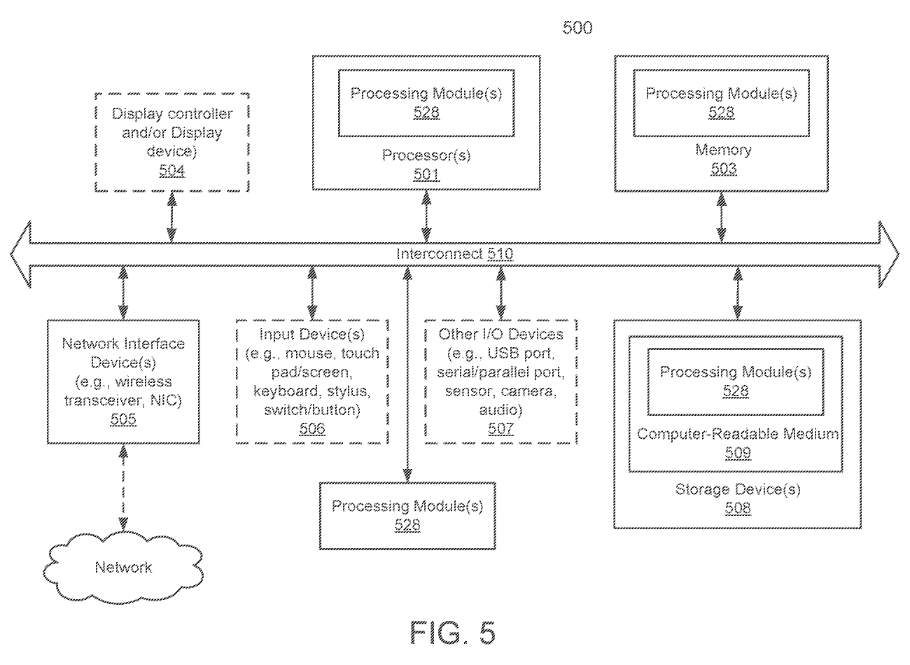

Such computer-implemented services may be provided to one or more users of the data processing system 102 and/or to users of other devices 103 (e.g., via the users of other devices 103 requesting such computer-implemented services from the data processing system 102). Conversely, the other devices 103 may also provide computer-implemented services to the data processing system 102. In embodiments, any of the data processing system 102 and the other devices 103 may implemented as a computing device (e.g., computing device of FIG. 5)

To provide the computer-implemented services, the system of FIG. 1 may include any number of the data processing system 102 and the other devices 103. Data processing system 102 and the other devices 103 may provide the computer-implemented services to their respective users and/or to other devices (not shown). Data processing system 102 and the other devices 103 may provide similar and/or different computer-implemented services. Data processing system 102 and the other devices 103 may also be organized in one or more deployments (e.g., server farms, remote storage environments, Cloud-RAN deployments, or the like) to collectively provide the computer-implemented services.

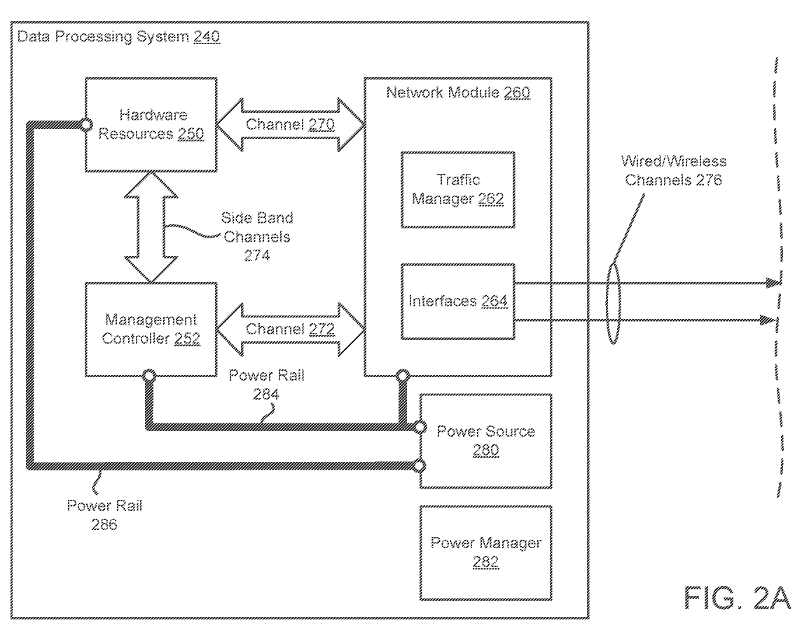

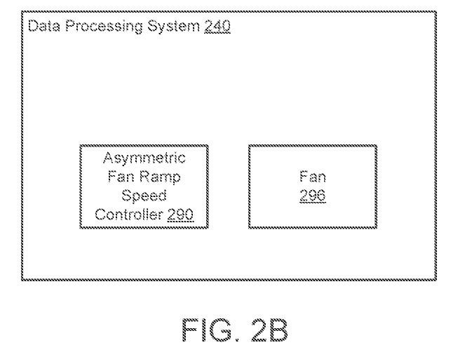

To provide the computer-implemented services, data processing systems 102A-102N may include various hardware components (e.g., processors, memory modules, storage devices, peripheral devices, etc.) and host various software components (e.g., operating systems, application, startup managers such as basic input-output systems, etc.). These hardware and software components (discussed in more detail below in FIG. 2A) may provide the computer-implemented services via their operation.

The software components may be implemented using various types of services. For example, each data processing system of the data processing systems 102A-102N may host various services that provide the computer-implemented service (e.g., application services) and/or that manage the operation of these services (e.g., management services). The aggregate (e.g., combination) of the management and application services may be a complete service that provide desired functionalities.

Any of the components illustrated in FIG. 1 may be operably connected to each other (and/or components not illustrated) with communication system 106. In an embodiment, communication system 106 includes one or more networks that facilitate communication between any number of components. The networks may include wired networks and/or wireless networks (e.g., and/or the Internet). The networks may operate in accordance with any number and/or types of communication protocols (e.g., such as the internet protocol).

While illustrated in FIG. 1 as including a limited number of specific components, a system in accordance with an embodiment may include fewer, additional, and/or different components than those illustrated therein.

Turning to FIG. 2A, a diagram illustrating an example data processing system 240 in accordance with an embodiment is shown. The data processing system 240 shown in FIG. 2A may be similar to data processing system 102 (and/or any of the other devices 103) shown in FIG. 1.

To provide computer-implemented services, data processing system 240 may include any quantity of hardware resources 250. Hardware resources 250 may be in-band hardware components, and may include a processor operably coupled to memory, storage, and/or other hardware components (e.g., fans, the asymmetric ran ramp speed controller 290 discussed in more detail below in FIG. 2B, sensors, or the like).

In embodiments, the processor (e.g., central processing unit (CPU)) that is part of the hardware resources 250 may be a main processor of the data processing system 240. This main processor may host various management entities such as operating systems (OS), drivers (e.g., OS-based and non-OS based drivers), OS stacks, firmware stacks, network stacks, and/or other software entities that provide various management functionalities. For example, the OS and drivers may provide abstracted access to various hardware resources. Likewise, the network stack may facilitate packaging, transmission, routing, and/or other functions with respect to exchanging data with other devices.

For example, the network stack may support transmission control protocol/internet protocol communication (TCP/IP) (e.g., the Internet protocol suite) thereby allowing the hardware resources 250 to communicate with other devices via packet switched networks and/or other types of communication networks.

The processor may also host various applications that provide the computer-implemented services. The applications may utilize various services provided by the management entities and use (at least indirectly) the network stack to communicate with other entities.

However, use of the network stack and the services provided by the management entities may place the applications at risk of indirect compromise. For example, if any of these entities trusted by the applications are compromised, then these entities may subsequently compromise the operation of the applications. For example, if various drivers and/or the communication stack are compromised, then communications to/from other devices may be compromised. If the applications trust these communications, then the applications may also be compromised.

For example, to communicate with other entities, an application may generate and send communications to a network stack and/or driver, which may subsequently transmit a packaged form of the communication via channel 270 to a communication component, which may then send the packaged communication (in a yet further packaged form, in some embodiments, with various layers of encapsulation being added depending on the network environment outside of data processing system 240) to another device via any number of intermediate networks (e.g., via wired/wireless channels 276 that are part of the networks).

To reduce the likelihood of the applications and/or other in-band entities from being indirectly compromised, data processing system 240 may include management controller 252 and network module 260. Each of these components of data processing system 240 is discussed below.

Management controller 252 may be implemented, for example, using a system on a chip or other type of independently operating computing device (e.g., a microcontroller or the like that is independent from the in-band components, such as hardware resources 250 of a host data processing system 240). Management controller 252 may provide various management functionalities for data processing system 240. For example, management controller 252 may monitor various ongoing processes performed by the in-band components, may manage power distribution, thermal management, and/or may perform other functions for managing data processing system 240. In some embodiments, the management controller 252 may act as the embedded controller of the data processing system 240. In some embodiments, the management controller 252 may be the sole embedded controller of the data processing system 240 (e.g., there is no separate embedded controller as part of the hardware resources 250).

In embodiments, the management controller 252 may be implemented as an embedded controller with separate memory (e.g., random access memory (RAM)) from that of the main processor. The embedded controller may also operate independently from the main processor (e.g., using its own secondary and independent processor) and perform independent functions such as, but not limited to: (i) receiving and processing signals from a keyboard or other input devices of the data processing system 240; (ii) retrieving thermal measurements (e.g., temperature measurements) from various components of the data processing system (e.g., from the sensors that are part of hardware resources 250), or the like); (iii) using the thermal measurements to control one or more fans installed within the data processing system 240 and/or to throttle the main processor; or the like.

In embodiments, the management controller 252 (acting as an embedded controller) may be configured to have sole control over all thermal readings (e.g., temperature measurements) of the thermal sensors installed in the data processing system 240. This advantageously creates (through the embedded controller) a single interface (e.g., a single API or the like) that can be called on (e.g., by the stacks of the main processor) when thermal readings are needed for thermal management of the data processing system 240. Use of the management controller 252 as the single interface for thermal readings advantageously provides improved software transparency and a cleaner architecture for the data processing system 240. When other components (e.g., the main processor, the asymmetric fan ramp speed controller 290, or the like) need to use the thermal readings, they may obtain the thermal readings from the management controller 252 (e.g., using an API call or the like).

In embodiments, to provide its functionalities, management controller 252 may be operably connected to various components via sideband channels 274 (in FIG. 2A, a limited number of sideband channels are included for illustrative purposes, it will be appreciated that management controller 252 may communicate with other components via any number of sideband channels). The sideband channels may be implemented using separate physical channels, and/or with a logical channel overlay over existing physical channels (e.g., logical division of in-band channels). The sideband channels may allow management controller 252 to interface with other components and implement various management functionalities such as, for example, general data retrieval (e.g., to snoop ongoing processes), telemetry data retrieval (e.g., to identify a health condition/other state of another component), function activation (e.g., sending instructions that cause the receiving component to perform various actions such as displaying data, adding data to memory, causing various processes to be performed), and/or other types of management functionalities. For example, the management controller may use sideband channels (e.g., inter-integrated circuit (I2C)/improved inter-integrated circuit (I3C) interfaces/channels, analog-to-digital converter (ADC) channels, or the like).

For example, to reduce the likelihood of indirect compromise of an application hosted by hardware resources 250, management controller 252 may enable information from other devices to be provided to the application without traversing the network stack and/or management entities of hardware resources 250. To do so, the other devices may direct communications including the information to management controller 252.

Management controller 252 may then, for example, send the information via sideband channels 274 to hardware resources 250 (e.g., to store it in a memory location accessible by the application, such as a shared memory location, a mailbox architecture, or other type of memory-based communication system) to provide it to the application. Thus, the application may receive and act on the information without the information passing through potentially compromised entities. Consequently, the information may be less likely to also be compromised, thereby reducing the possibility of the application becoming indirectly compromised. Similarly, processes may be used to facilitate outbound communications from the applications.

Management controller 252 may be operably connected to communication components of data processing system 240 via separate channels (e.g., 272) from the in-band components, and may implement or otherwise utilize a distinct and independent network stack (e.g., TCP/IP). Consequently, management controller 252 may communicate with other devices independently of any of the in-band components (e.g., does not rely on any hosted software, hardware components, etc.). Accordingly, compromise of any of hardware resources 250 and hosted components may not result in indirect compromise of any management controller 252, and entities hosted by management controller 252.

To facilitate communication with other devices, data processing system 240 may include network module 260. Network module 260 may provide communication services for in-band components and out-of-band components (e.g., management controller 252) of data processing system. To do so, network module 260 may include traffic manager 262 and interfaces 264.

Traffic manager 262 may include functionality to (i) discriminate traffic directed to various network endpoints advertised by data processing system 240, and (ii) forward the traffic to/from the entities associated with the different network endpoints. For example, to facilitate communications with other devices, network module 260 may advertise different network endpoints (e.g., different media access control address/internet protocol addresses) for the in-band components and out-of-band components. Thus, other entities may address communications to these different network endpoints. When such communications are received by network module 260, traffic manager 262 may discriminate and direct the communications accordingly (e.g., over channel 270 or channel 272, in the example shown in FIG. 2A, it will be appreciated that network module 260 may discriminate traffic directed to any number of data units and direct it accordingly over any number of channels).

Accordingly, traffic directed to management controller 252 may never flow through any of the in-band components. Likewise, outbound traffic from the out-of-band component may never flow through the in-band components.

Thus, if in-band components of data processing system 240 are unsecured and/or compromised (e.g., by a malicious party), then the computing instructions sent using out-of-band components and via out-of-band communication channels may be less likely to be intercepted and/or modified (e.g., by the malicious party), and the operation of data processing system 240 may be more likely to be updated according to its reported location.

To support inbound and outbound traffic, network module 260 may include any number of interfaces 264. Interfaces 264 may be implemented using any number and type of communication devices which may each provide wired and/or wireless communication functionality. For example, interfaces 264 may include a wireless wide area network (WWAN) card, a Wi-Fi card, a wireless local area network card, a wired local area network card, an optical communication card, and/or other types of communication components. These components may support any number of wired/wireless channels 276.

Thus, from the perspective of an external device, the in-band components and out-of-band components of data processing system 240 may appear to be two independent network entities, that may be independently addressable and/or otherwise unrelated to one another.

To facilitate management of data processing system 240 over time, hardware resources 250, management controller 252 and/or network module 260 may be positioned in separately controllable power domains. By being positioned in these separate power domains, different subsets of these components may remain powered while other subsets are unpowered.

For example, management controller 252 and network module 260 may remain powered while hardware resources 250 is unpowered. Consequently, management controller 252 may remain able to communicate with other devices even while hardware resources 250 are inactive. Similarly, management controller 252 may perform various actions while hardware resources 250 are not powered and/or are otherwise inoperable, unable to cooperatively perform various process, are compromised, and/or are unavailable for other reasons. Therefore, if hardware resources 250 become unavailable (e.g., due to being unpowered), then out-of-band components may remain powered, allowing network module 260 to continue to generate location data for data processing system 240.

To implement the separate power domains, data processing system 240 may include a power source (e.g., 280) that separately supplies power to power rails (e.g., power rail 284, power rail 286) that power the respective power domains. Power from the power source (e.g., a power supply, battery, etc.) may be selectively provided to the separate power rails to selectively power the different power domains. A power manager (e.g., 282) that may manage power from power source 280 may be supplied to the power rails. Management controller 252 may cooperate with power manager 282 to manage supply of power to these power domains.

In FIG. 2A, an example implementation of separate power domains using power rails 284-286 is shown. The power rails may be implemented using, for example, bus bars or other types of transmission elements capable of distributing electrical power. While not shown, it will be appreciated that the power domains may include various power management components (e.g., fuses, switches, etc.) to facilitate selective distribution of power within the power domains.

Turning now to FIG. 2B, FIG. 2B shows another example of the data processing system 240 shown in FIG. 2A. In particular, FIG. 2B shows an abridged (e.g., simplified) version of the data processing system 240 with certain components visually removed for simplicity. Said another way, although not shown in FIG. 2B, the data processing system 240 of FIG. 2B still includes all of the components shown in FIG. 2A.

As shown in FIG. 2B, data processing system 240 includes an asymmetric fan ramp speed controller 290, and a fan 296. Each of these components will be described below.

Fan 296 may be any type of mechanical fan (e.g., motorized, magnet controller, or the like) used in computing devices for cooling of (e.g., an entirety or just specific component(s) of) the computing device. For example, the fan 296 may be a power supply unit (PSU) fan, a CPU fan, a GPU fan, a case fan, a laptop fan, or the like.

In embodiments, the data processing system 240 may have any number of fan 296.

Asymmetric fan ramp speed controller 290 may be configured using hardware, software, or a combination of both thereof. Asymmetric fan ramp speed controller 290 may be configured to control the ramp speed of fan 296. In particular, asymmetric fan ramp speed controller 290 may be configured to realize asymmetric fan ramp speed control over fan 296, which will be discussed in more detail below in reference to FIG. 2B.

In embodiments, may be implemented using (e.g., individually) the main processor, the management controller 252, an integrated circuit (IC) (e.g., including its own processor and memory) completely separate from the main processor and the management controller 252, or may be implemented as a combination of any of these components working in unison.

For example, in one example implementation of embodiments disclosed herein, the asymmetric fan ramp speed control operations/processes (e.g., to be discussed below in reference to FIG. 2B) of the asymmetric fan ramp speed controller 290 may be integrated into existing firmware of the management controller 252 (e.g., by adding additional functions to already existing fan control functions and operations of the management controller 252). Alternatively, the asymmetric fan ramp speed control operations/processes of the asymmetric fan ramp speed controller 290 may be realized (i.e., implemented) using any other of the components (individually or in combination) discussed in the previous paragraph without departing from the scope of embodiments disclosed herein.

In embodiments, the asymmetric fan ramp speed controller 290 may control the fan 296 using any suitable fan control framework and/or techniques (e.g., using a linear fan control thermal framework, using a thermal fan control table including pulse width modulation (PWM)/revolutions per minute (RPM) values associated with various measured temperatures, or the like) without departing from the scope of embodiments disclosed herein.

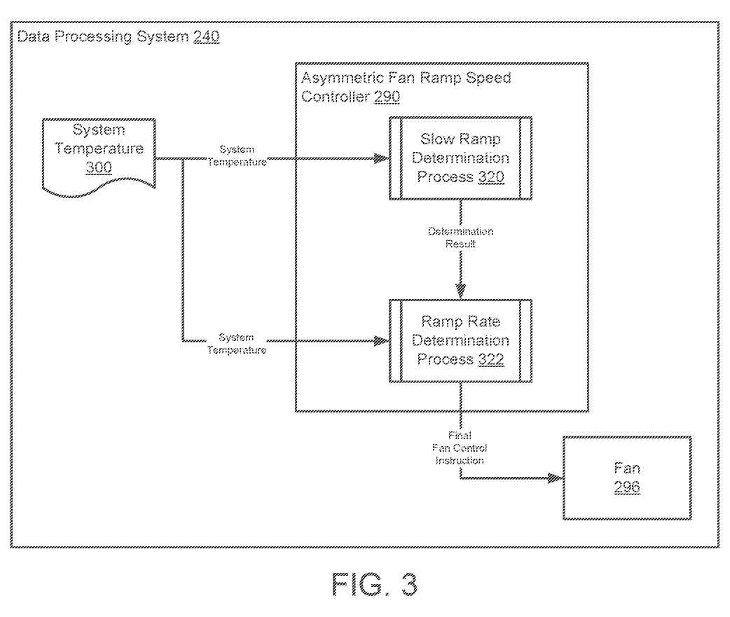

To further clarify embodiments disclosed herein, a data flow diagram in accordance with one or more embodiments disclosed herein is shown in FIG. 3. In these diagrams, flows of data and processing of data are illustrated using different sets of shapes. A first set of shapes (e.g., 300, etc.) is used to represent data structures (e.g., files, data packets, or the like), a second set of shapes (e.g., 320. 322,etc.) is used to represent processes performed using and/or that generate data, and a third set of shapes (e.g., 240, 290, 296, etc.) is used to represent the components (e.g., the devices, hardware and/or software components, or the like discussed above in reference to FIGS. 1-2B) that perform the processes shown using the second set of shapes.

As shown in FIG. 3, system temperature 300 may be obtained. The system temperature 300 may include the temperatures of any or all components within the data processing system 240. For example, the system temperature 300 may include temperatures for individual components such as the CPU temperature, the GPU temperature, the management controller 252 temperature or the like. The system temperature 300 may also include an aggregate (e.g., sum, average, or the like) of one or more of these temperatures to indicate a temperature of either the entire data processing system 240 or of portions (e.g., internal sections) of the data processing system 240.

Any type of temperature value reflecting one or more types of temperatures recorded within the data processing system 240 may be included in system temperature 300 without departing from the scope of embodiments disclosed herein.

The system temperature 300 may be obtained (e.g., provided to, transmitted to, received by, or the like) by asymmetric fan ramp speed controller 290. In embodiments, the asymmetric fan ramp speed controller 290 may retrieve the system temperature 300 directly from the measurement source (e.g., any one of the sensors installed within data processing system 240 configured to measure temperature). Alternatively, the asymmetric fan ramp speed controller 290 may retrieve the system temperature 300 from management controller 252 that is acting as the single interface (e.g., a single API or the like) that can be called on (e.g., by the stacks of the main processor, by the stacks of a separate processor of the asymmetric fan ramp speed controller 290, or the like) when thermal readings are needed for thermal management of the data processing system 240

Once obtained, the system temperature 300 may be ingested into slow ramp determination process 320 and ramp rate determination process 322 implemented by the asymmetric fan ramp speed controller 290. In embodiments, slow ramp determination process 320 and ramp rate determination process 322 may be executed simultaneously by the asymmetric fan ramp speed controller 290. In embodiments, even when executed simultaneously, the results of these two processes may be combined first (e.g., to generate final fan control instructions) before any instructions are provided to fan 296.

In slow ramp determination process 320, the system temperature 300 is compared to previously captured instances of the system temperature 300 to determine whether a most recent instance (e.g., the currently obtained instance) of the system temperature 300 has increased, decreased, or remained the same.

For example, assume that two instances of the system temperature 300 are obtained at a first point in time (e.g., 7:00 PM) and a second point in time (e.g., 6:59) before the first point in time. Slow ramp determination process 320 may be configured to determine whether the later obtained instance (here the instance obtained at 7:00 PM) is higher, lower, or identical (e.g., the same) as the previous instance.

Although this example shows the system temperature 300 being obtained every minute, one of ordinary skill will appreciate that the interval at which the system temperature 300 is obtained may be set to any amount of time (e.g., every second, every 30 milliseconds, every 10 seconds, or the like) based on a pre-set interval defined by a user and/or administrator of the data processing system 240, without departing from the scope of embodiments disclosed herein.

In the event that the slow ramp determination process 320 determines that the most recently obtained instance of the system temperature 300 has increased, the slow ramp determination process outputs a determination result indicating that a fan ramp rate (e.g., an original fan ramp rate determined using ramp rate determination process 322 discussed in more detail below) of fan 296 should be slowed down.

In the event that the slow ramp determination process 320 determines that the most recently obtained instance of the system temperature 300 has decreased, the slow ramp determination process outputs a determination result indicating that a fan ramp rate (e.g., the original fan ramp rate determined using ramp rate determination process 322) of fan 296 should be increased (e.g., sped-up) or should remain the same.

In the event that the slow ramp determination process 320 determines that the most recently obtained instance of the system temperature 300 has remained the same, the slow ramp determination process outputs a determination result indicating that a fan ramp rate (original fan ramp rate determined using ramp rate determination process 322) of fan 296 should remain the same or should not increase (e.g., should not be sped-up).

In embodiments, ramp rate determination process 322 may use the system temperature to determine (e.g., using any suitable fan control framework and/or techniques such as using a linear fan control thermal framework, using a thermal fan control table including pulse width modulation (PWM)/revolutions per minute (RPM) values associated with various measured temperatures, or the like) a target fan speed and an original fan ramp rate to get to the target fan speed from a current fan speed.

The target fan speed may be value (e.g., in RPM) indicative of how quickly the fan 296 needs to rotates to cool the data processing system 240 based on the values observed in the system temperature 300. For example, the target fan speed may be higher if the system temperature is high and vice versa.

The original fan ramp rate may be a value (in ramp rate per second, or the like) to be utilized by the ramp to reach the target fan speed from a current fan speed at which the fan 296 is operating. In embodiments, both the target fan speed and the original fan ramp rate may be obtained, for example, from the thermal fan control table stored by the asymmetric fan ramp speed controller 290.

Alternatively, the target fan speed and the original fan ramp rate may be calculated by the asymmetric fan ramp speed controller 290 using one or more sets of fan control rules and/or policies stored in the asymmetric fan ramp speed controller 290. Other suitable methods and/or techniques for determining a target fan speed and a fan ramp rate to reach the target fan speed based on a measured temperature of the data processing system 240 may also be used without departing from the scope of embodiments disclosed herein.

In embodiments, the asymmetric fan ramp speed controller 290 may combine the results of the slow ramp determination process 320 and ramp rate determination process 322 into final fan control instructions. In particular, the final fan control instructions may include: (i) the target fan speed; (ii) the original fan ramp rate; and (iii) instructions for speeding up, slowing down, or doing nothing to the original fan ramp rate.

As a result, in embodiments disclosed herein, using final fan control instructions, the asymmetric fan ramp speed controller 290 may advantageously control the fan 296 to ramp up and down asymmetrically (e.g., ramp up and down at different speeds). In particular, any fan ramp ups (e.g., any increase in the fan speed when the system needs cooling after heating up) may be configured to be slowed down such that these ramp ups are acoustically less noticeable (or not noticeable at all) to a user of the data processing system.

Additionally, any fan ramp downs (e.g., any decrease in fan speed when the system no longer needs cooling after the system has cooled down or is cooling down) may be configured to be sped-up such that these ramp downs become more noticeable (e.g., and better appreciated) by the user of the data processing system.

For example, consider the following first use case of embodiments disclosed herein. In this first use case, the user may be working on the data processing system 240 and has multiple computer-implemented services (e.g., multiple applications or the like) running. These computer-implemented services may be implementing compute-intensive workloads (e.g., running machine learning models or the like). As a result, the temperature of the data processing system 240 (e.g., the CPU temperature or the like) may rise quickly (e.g., get very hot) requiring a higher target fan speed to be implemented to provide effective cooling for the data processing system 240. Rather than increasing the current fan speed to the higher target fan speed at the original ramp rate, the original ramp rate may be slowed down (e.g., at a 2X, 3X, or 10X ramp rate reduction) such that the user is barely able to notice that the fan 296 is working hard to cool the data processing system 240

As another example, consider the following first use case of embodiments disclosed herein. In this second use case, the same user in the first use case stops all the compute-intensive workloads on the data processing system 240 and switches to executing less compute-intensive workloads (e.g., web browsing, reading emails, or the like). The data processing system 240 now consumes much less power resulting in a cool down of the data processing system. As a result of such cool down, the fan 296 no longer needs to operate at the higher target fan speed and can be slowed down to a lower (e.g., slower) target fan speed. When the fan 296 is being ramped down to reach the lower (e.g., slower) target fan speed, the ramp rate may be increased to allow the user to hear that the fan is ramping down, which provides the user with the satisfaction of knowing that the data processing system 240 has cooled down (or is in the process of cooling down).

As a result, the asymmetric ramp speed control of embodiments disclosed herein advantageously reduces acoustic discomfort when a system heats up and also advantageously increases user satisfaction when the system cools down.

Any of the processes illustrated using the second set of shapes (shown in FIG. 3) may be performed, in part or whole, by digital processors (e.g., central processors, processor cores, etc.) that execute corresponding instructions (e.g., computer code/software). Execution of the instructions may cause the digital processors to initiate performance of the processes. Any portions of the processes may be performed by the digital processors and/or other devices. For example, executing the instructions may cause the digital processors to perform actions that directly contribute to performance of the processes, and/or indirectly contribute to performance of the processes by causing (e.g., initiating) other hardware components to perform actions that directly contribute to the performance of the processes.

Any of the processes illustrated using the second set of shapes may be performed, in part or whole, by special purpose hardware components such as digital signal processors, application specific integrated circuits, programmable gate arrays, graphics processing units, data processing units, and/or other types of hardware components. These special purpose hardware components may include circuitry and/or semiconductor devices adapted to perform the processes. For example, any of the special purpose hardware components may be implemented using complementary metal-oxide semiconductor-based devices (e.g., computer chips).

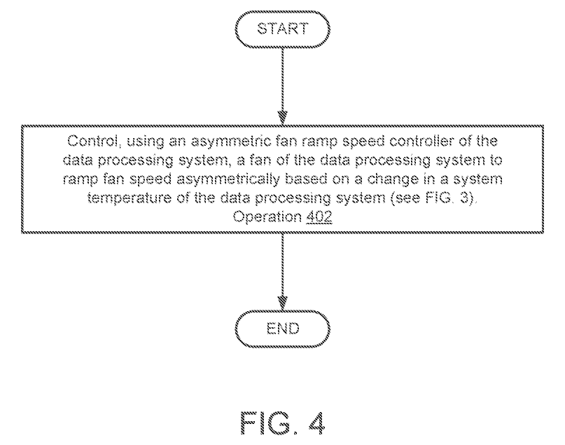

As discussed above, the components of FIGS. 1-3 may perform various methods for cooling a data processing system. FIG. 4 illustrates an example method that may be performed by the components of FIGS. 1-3. For example, any of the data processing system 102, and/or the other devices 103 shown in FIG. 1 may include components (e.g., shown in FIGS. 2A-2B) that are capable of performing all or a portion of the method of FIG. 4. In the diagram discussed below and shown in FIG. 4, any of the operations may be repeated, performed in different orders, and/or performed in parallel with or in a partially overlapping in time manner with other operations.

In Operation 402, and as discussed above in reference to FIGS. 2B-3, an asymmetric fan ramp speed controller of the data processing system may control a fan (or a plurality of fans) of the data processing system to ramp fan speed asymmetrically based on a change in a system temperature of the data processing system.

In embodiments, based on the change in the system temperature, the fan may be controlled to ramp up at a first ramp speed slower than a second ramp speed at which the fan is controlled to ramp down. As a result, the noise (e.g., acoustics) associated with the fan ramping up when the data processing system needs cool (e.g., from heating up) may be eliminated while the noise (e.g., acoustics) associated with the fan ramping down when the data processing system no longer needs cooling or needs less cooling (e.g., from cooling down) may be highlighted to a user of the data processing system.

Said another way, controlling the fan to ramp up at the first ramp speed slower than the second ramp speed at which the fan is controlled to ramp down may advantageously reduce any acoustic discomfort experienced by a user of the data processing system when the data processing system heats up (e.g., as a result of hearing the fan ramping up).

The method may end following operation 402.

Any of the components illustrated in FIGS. 1-4 may be implemented with one or more computing devices. Turning to FIG. 5, a block diagram illustrating an example of a data processing system (e.g., a computing device) in accordance with an embodiment is shown. For example, system 500 may represent any of data processing systems described above performing any of the processes or methods described above. System 500 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 500 is intended to show a high-level view of many components of the computer system. However, it is to be understood that additional components may be present in certain implementations and furthermore, different arrangement of the components shown may occur in other implementations.

System 500 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 500 includes processor 501, memory 503, and devices 505-508 via a bus or an interconnect 510. Processor 501 may represent a single processor or multiple processors with a single processor core or multiple processor cores included therein. Processor 501 may represent one or more general-purpose processors such as a microprocessor, a central processing unit (CPU), or the like.

More particularly, processor 501 may be a complex instruction set computing (CISC) microprocessor, reduced instruction set computing (RISC) microprocessor, very long instruction word (VLIW) microprocessor, or processor implementing other instruction sets, or processors implementing a combination of instruction sets.

Processor 501 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 501, which may be a low power multi-core processor socket such as an ultra-low voltage processor, may act as a main processing unit and central hub for communication with the various components of the system. Such processor can be implemented as a system on chip (SoC). Processor 501 is configured to execute instructions for performing the operations discussed herein. System 500 may further include a graphics interface that communicates with optional graphics subsystem 504, which may include a display controller, a graphics processor, and/or a display device.

Processor 501 may communicate with memory 503, which in one embodiment can be implemented via multiple memory devices to provide for a given amount of system memory. Memory 503 may include one or more volatile storage (or memory) devices such as random-access memory (RAM), dynamic RAM (DRAM), synchronous DRAM (SDRAM), static RAM (SRAM), or other types of storage devices. Memory 503 may store information including sequences of instructions that are executed by processor 501, or any other device.

For example, executable code and/or data of a variety of operating systems, device drivers, firmware (e.g., input output basic system or BIOS), and/or applications can be loaded in memory 503 and executed by processor 501. An operating system can be any kind of operating systems, such as, for example, Windows^{®} operating system from Microsoft^{®}, Mac OS^{®}/iOS^{®} from Apple, Android^{®} from Google^{®}, Linux^{®}, Unix^{®}, or other real-time or embedded operating systems such as VxWorks.

System 500 may further include IO devices such as devices (e.g., 505, 506, 507, 508) including network interface device(s) 505, optional input device(s) 506, and other optional IO device(s) 507. Network interface device(s) 505 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 506 may include a mouse, a touch pad, a touch sensitive screen (which may be integrated with a display device of optional graphics subsystem 504), a pointer device such as a stylus, and/or a keyboard (e.g., physical keyboard or a virtual keyboard displayed as part of a touch sensitive screen). For example, input device(s) 506 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 507 may include an audio device. An audio device may include a speaker and/or a microphone to facilitate voice-enabled functions, such as voice recognition, voice replication, digital recording, and/or telephony functions. Other IO devices 507 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 507 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 510 via a sensor hub (not shown), while other devices such as a keyboard or thermal sensor may be controlled by an embedded controller (not shown), dependent upon the specific configuration or design of system 500.

To provide for persistent storage of information such as data, applications, one or more operating systems and so forth, a mass storage (not shown) may also couple to processor 501. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 501, e.g., via a serial peripheral interface (SPI). This flash device may provide for non-volatile storage of system software, including a basic input/output software (BIOS) as well as other firmware of the system.

Storage device 508 may include computer-readable storage medium 509 (also known as a machine-readable storage medium or a computer-readable medium) on which is stored one or more sets of instructions or software (e.g., processing module, unit, and/or processing module/unit/logic 528) embodying any one or more of the methodologies or functions described herein. Processing module/unit/logic 528 may represent any of the components described above. Processing module/unit/logic 528 may also reside, completely or at least partially, within memory 503 and/or within processor 501 during execution thereof by system 500, memory 503 and processor 501 also constituting machine-accessible storage media. Processing module/unit/logic 528 may further be transmitted or received over a network via network interface device(s) 505.

Computer-readable storage medium 509 may also be used to store some software functionalities described above persistently. While computer-readable storage medium 509 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 528, components and other features described herein can be implemented as discrete hardware components or integrated in the functionality of hardware components such as ASICS, FPGAs, DSPs, or similar devices. In addition, processing module/unit/logic 528 can be implemented as firmware or functional circuitry within hardware devices. Further, processing module/unit/logic 528 can be implemented in any combination hardware devices and software components.

Note that while system 500 is illustrated with various components of a data processing system, it is not intended to represent any particular architecture or manner of interconnecting the components; as such details are not germane to embodiments disclosed herein. It will also be appreciated that network computers, handheld computers, mobile phones, servers, and/or other data processing systems which have fewer components, or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system’s registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A method for controlling a fan of a data processing system, the method comprising:
controlling, using an asymmetric fan ramp speed controller of the data processing system, the fan to ramp fan speed asymmetrically based on a change in a system temperature of the data processing system.

2. The method of claim 1, wherein, based on the change in the system temperature, the fan is controlled to ramp up at a first ramp speed slower than a second ramp speed at which the fan is controlled to ramp down.

3. The method of claim 2, wherein the controlling comprises:
obtaining, by the asymmetric fan ramp speed controller, a first instance of the system temperature at a first point in time;
using the first instance of the system temperature to determine:
a target fan speed, and
original fan ramp rate to get to the target fan speed from a current fan speed; and
determining whether the first instance of the system temperature has increased since a last time, prior to the first point in time, the asymmetric fan ramp speed controller has obtained another instance of the system temperature.

4. The method of claim 3, wherein the controlling further comprises in a first instance at the first point in time where the asymmetric fan ramp speed controller has determined that the first instance of the system temperature has increased:
making a first determination, based on determining that the first instance of the system temperature has increased, that the original fan ramp rate should be slowed down; and
controlling, based on the first determination, the fan to reach the target fan speed at a slowed down rate of the original fan ramp rate.

5. The method of claim 4, wherein the controlling further comprises in a second instance at the first point in time where the asymmetric fan ramp speed controller has determined that the first instance of the system temperature has neither increased nor decreased:
making a second determination, based on determining that the first instance of the system temperature has neither increased nor decreased, that the original fan ramp rate should remain unchanged; and
.controlling, based on the second determination, the fan to reach the target fan speed at the original fan ramp rate.

6. The method of claim 5, wherein the controlling further comprises in a third instance at the first point in time where the asymmetric fan ramp speed controller has determined that the first instance of the system temperature has decreased:
. a third determination, based on determining that the first instance of the system temperature has decreased, that the original fan ramp rate should be sped-up; and
. , based on the third determination, the fan to reach the target fan speed at a sped-up rate of the original fan ramp rate.

7. The method of claim 2, wherein controlling the fan to ramp up at the first ramp speed slower than the second ramp speed at which the fan is controlled to ramp down reduces an acoustic discomfort experienced by a user of the data processing system when the data processing system heats up.

8. A non-transitory machine-readable medium having instructions stored therein, which when executed by a processor, cause the processor to perform operations for controlling a fan of a data processing system, the operations comprising:
controlling, using an asymmetric fan ramp speed controller of the data processing system, the fan to ramp fan speed asymmetrically based on a change in a system temperature of the data processing system.

9. The non-transitory machine-readable medium of claim 8, wherein, based on the change in the system temperature, the fan is controlled to ramp up at a first ramp speed slower than a second ramp speed at which the fan is controlled to ramp down.

10. The non-transitory machine-readable medium of claim 9, wherein the controlling comprises:
obtaining, by the asymmetric fan ramp speed controller, a first instance of the system temperature at a first point in time;
using the first instance of the system temperature to determine:
a target fan speed, and
original fan ramp rate to get to the target fan speed from a current fan speed; and
determining whether the first instance of the system temperature has increased since a last time, prior to the first point in time, the asymmetric fan ramp speed controller has obtained another instance of the system temperature.

11. The non-transitory machine-readable medium of claim 10, wherein the controlling further comprises in a first instance at the first point in time where the asymmetric fan ramp speed controller has determined that the first instance of the system temperature has increased:
. a first determination, based on determining that the first instance of the system temperature has increased, that the original fan ramp rate should be slowed down; and
. , based on the first determination, the fan to reach the target fan speed at a slowed down rate of the original fan ramp rate.

12. The non-transitory machine-readable medium of claim 11, wherein the controlling further comprises in a second instance at the first point in time where the asymmetric fan ramp speed controller has determined that the first instance of the system temperature has neither increased nor decreased:
making a second determination, based on determining that the first instance of the system temperature has neither increased nor decreased, that the original fan ramp rate should remain unchanged; and
controlling, based on the second determination, the fan to reach the target fan speed at the original fan ramp rate.

13. The non-transitory machine-readable medium of claim 12, wherein the controlling further comprises in a third instance at the first point in time where the asymmetric fan ramp speed controller has determined that the first instance of the system temperature has decreased:
making a third determination, based on determining that the first instance of the system temperature has decreased, that the original fan ramp rate should be sped-up; and
controlling, based on the third determination, the fan to reach the target fan speed at a sped-up rate of the original fan ramp rate.

14. The non-transitory machine-readable medium of claim 9, wherein controlling the fan to ramp up at the first ramp speed slower than the second ramp speed at which the fan is controlled to ramp down reduces an acoustic discomfort experienced by a user of the data processing system when the data processing system heats up.

15. A data processing system comprising:
a fan;
a processor; and
a memory coupled to the processor, the memory storing instructions that, when executed by the processor, causes the data processing system to perform operations for controlling the fan, the operations comprising:
controlling, using asymmetric fan ramp speed controller of the data processing system, the fan to ramp fan speed asymmetrically based on a change in a system temperature of the data processing system.

16. The data processing system of claim 15, wherein, based on the change in the system temperature, the fan is controlled to ramp up at a first ramp speed slower than a second ramp speed at which the fan is controlled to ramp down.

17. The data processing system of claim 16, wherein the controlling comprises:
obtaining, by the asymmetric fan ramp speed controller, a first instance of the system temperature at a first point in time;
using the first instance of the system temperature to determine:
a target fan speed, and
original fan ramp rate to get to the target fan speed from a current fan speed; and
determining whether the first instance of the system temperature has increased since a last time, prior to the first point in time, the asymmetric fan ramp speed controller has obtained another instance of the system temperature.

18. The data processing system of claim 17, wherein the controlling further comprises in a first instance at the first point in time where the asymmetric fan ramp speed controller has determined that the first instance of the system temperature has increased:
making a first determination, based on determining that the first instance of the system temperature has increased, that the original fan ramp rate should be slowed down; and
controlling, based on the first determination, the fan to reach the target fan speed at a slowed down rate of the original fan ramp rate.

19. The data processing system of claim 18, wherein the controlling further comprises in a second instance at the first point in time where the asymmetric fan ramp speed controller has determined that the first instance of the system temperature has neither increased nor decreased:
making a second determination, based on determining that the first instance of the system temperature has neither increased nor decreased, that the original fan ramp rate should remain unchanged; and
controlling, based on the second determination, the fan to reach the target fan speed at the original fan ramp rate.

20. The data processing system of claim 19, wherein the controlling further comprises in a third instance at the first point in time where the asymmetric fan ramp speed controller has determined that the first instance of the system temperature has decreased:
making a third determination, based on determining that the first instance of the system temperature has decreased, that the original fan ramp rate should be sped-up; and
controlling, based on the third determination, the fan to reach the target fan speed at a sped-up rate of the original fan ramp rate.
